(19) United States
(12) Patent Application Publication
(10) Pub. No.: US 2024/0235141 A1
(43) Pub. Date: Jul. 11, 2024

(54) ELECTRONIC DEVICE MANUFACTURING SYSTEM AND METHOD

(71) Applicant: ULTRA DISPLAY TECHNOLOGY CORP., TAIPEI CITY (TW)

(72) Inventor: Hsien-Te CHEN, Taipei City (TW)

(21) Appl. No.: 18/404,257

(22) Filed: Jan. 4, 2024

(30) Foreign Application Priority Data
Jan. 11, 2023 (TW) 112101264

(51) Int. Cl. H01R 43/02

(52) U.S. Cl. CPC H01R 43/0221

(57) ABSTRACT

An electronic device manufacturing system includes a fixture, a target platform, wire mechanisms and a wire breaking mechanism. The fixture has a substrate defining plural channels. The target platform is located at one side of the fixture and defines a plane and plural target positions. Each wire mechanism has a shaft and a wire. The channels of the fixture correspond to at least part of the target positions, and the wire mechanisms correspond to the channels, respectively. The wire of each wire mechanism passes through the corresponding channel, and the fixed end thereof is located at the other side of the fixture, while the free end thereof is located on the target platform and corresponds to one of the target positions. The wire breaking mechanism is located between the fixture and the target platform for cutting the wires so as to form plural wire segments.

### CROSS REFERENCE TO RELATED APPLICATIONS

This Non-provisional application claims priority under 35 U.S.C. § 119(a) on Patent Application No(s). 112101264 filed in Taiwan, Republic of China on Jan. 11, 2023, the entire contents of which are hereby incorporated by reference.

### BACKGROUND

### Technology Field

The present disclosure relates to a system and a method, and in particular, to a manufacturing system and a manufacturing method of an electronic device that have the advantages of simple manufacturing processes, low cost and environmental friendly.

### Description of Related Art

In the manufacturing process of electronic devices, especially optoelectronic devices, in order to electrical connecting the circuit layers on the upper surface and the lower surface of the substrate, the conventional method is to drill holes in the substrate first, and then form a conductive film in the hole by chemical plating and/or the electroplating, so that the conductive film formed in the hole can connect the circuit layer on the upper surface to the circuit layer on the lower surface, thereby achieving the electrical connection of the circuit layers on the upper and lower surfaces of the substrate in the electronic device.

However, it is difficult to form a conductive film in the hole with a high depth-to-diameter ratio (i.e., the depth of the hole is much greater than the diameter of the hole) by the conventional chemical plating or electroplating process.

### SUMMARY

One or more exemplary embodiments of this disclosure are to provide a manufacturing system and a manufacturing method of an electronic device.

A manufacturing system of an electronic device of one exemplary embodiment includes a fixture, a target platform, a plurality of wire mechanisms, and a wire breaking mechanism. The fixture has a substrate, and the substrate defines a plurality of channels. The target platform is located at one side of the fixture, and defines a plane and a plurality of target positions, which are defined on the plane. Each of the wire mechanisms has a shaft and a wire wrapped around the shaft. Each of the wires is defined with a fixed end wrapped around the shaft and a free end opposite to the fixed end. The channels of the fixture correspond to at least part of the target positions of the target platform, and the wire mechanisms correspond to the channels, respectively. The free end of each wire corresponds to one of the channels, and corresponds to one of the target positions that corresponds to the corresponding channel. The wire of each wire mechanism passes through the corresponding channel of the fixture. The fixed end of the wire is located at the other side of the fixture away from the target platform, and the free end of the wire is located on the target platform and corresponds to one of the target positions. The wire breaking mechanism is located between the fixture and the target platform, and is configured to cut the wires so as to form a plurality of wire segments.

In one exemplary embodiment, each end of each channel defines a channel opening. In each of the channels, the channel opening close to the target platform is not greater than the other channel opening away from the target platform.

In one exemplary embodiment, the channel opening close to the target platform is not greater than 70 μm.

In one exemplary embodiment, each of the channels is defined with a hole diameter not less than 25 μm.

In one exemplary embodiment, each of the wires is defined with a wire diameter not less than 15 μm.

In one exemplary embodiment, the hole diameter of the channels is greater than the wire diameter of the wires.

In one exemplary embodiment, the substrate further defines a top surface and a wire-forward direction, each of the wires moves in the wire-forward direction, and the wire-forward direction is perpendicular to the top surface.

In one exemplary embodiment, the manufacturing system further includes a guiding mechanism configured to guide the wires toward the channels of the fixture correspondingly.

In one exemplary embodiment, the electronic device is accommodated in the target platform, and the electronic device defines a plurality of through holes. Each of the through holes corresponds to one of the target positions. The free end of the wire of each wire mechanism passes through the corresponding through hole and is located at one side of the electronic device away from the fixture, and the wire breaking mechanism cuts and welds one end of each wire segment to another side of the electronic device.

In one exemplary embodiment, the manufacturing system further includes a welding mechanism. The electronic device is accommodated in the target platform, and the electronic device defines a plurality of through holes. Each through hole corresponds to one of the target positions. The welding mechanism is located at one side of the electronic device away from the fixture, and the welding mechanism welds the free end of each wire to the side of the electronic device.

A manufacturing method of an electronic device of one exemplary embodiment includes the steps of: providing a manufacturing system, wherein the manufacturing system includes a target platform, a fixture, a plurality of wire mechanisms and a wire breaking mechanism; providing a substrate on the target platform, wherein the substrate has two opposite surfaces, a circuit layer arranged on at least one of the two surfaces, and a plurality of through holes communicating the two surfaces, the through holes correspond to a plurality of target positions of the target platform respectively, and each of the through holes defines two hole openings; the plurality of wire mechanisms providing a plurality of wires and leading the wires toward the substrate in a wire-forward direction of the fixture, so that the free end of each wire enters corresponding one of plural channels of the fixture and one of the through holes corresponding to the channel until the free end is exposed from one of the hole openings close to the target platform; and activating the wire breaking mechanism to apply a cutting impact to the wires in a direction parallel to the surface of the substrate adjacent to the fixture to form a plurality of wire segments.

In one exemplary embodiment, the cutting impact is a laser energy.

In one exemplary embodiment, the manufacturing method further includes a step of: welding one end of each wire segment to the circuit layer of the electronic device.

In one exemplary embodiment, the step of welding is performed with a laser energy.

### BRIEF DESCRIPTION OF THE DRAWINGS

The disclosure will become more fully understood from the detailed description and accompanying drawings, which are given for illustration only, and thus are not limitative of the present disclosure, and wherein:

FIGS. 1 to 3 are different schematic diagrams showing the manufacturing system of an electronic device according to an embodiment of this disclosure; and

FIG. 4 is a flow chart of a manufacturing method of an electronic device according to an embodiment of this disclosure.

### DETAILED DESCRIPTION OF THE DISCLOSURE

The present disclosure will be apparent from the following detailed description, which proceeds with reference to the accompanying drawings, wherein the same references relate to the same elements. The drawings of the following embodiments only illustrate the relative relationship between elements or units, and do not represent the actual size or proportion of the elements or units.

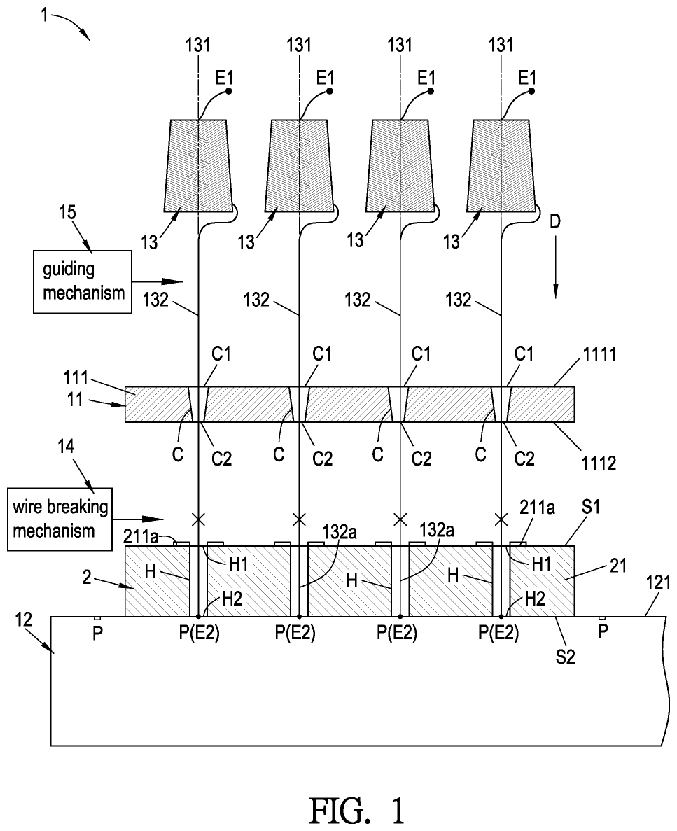

FIGS. 1 to 3 are different schematic diagrams showing the manufacturing system 1 of an electronic device 2 according to an embodiment of this disclosure.

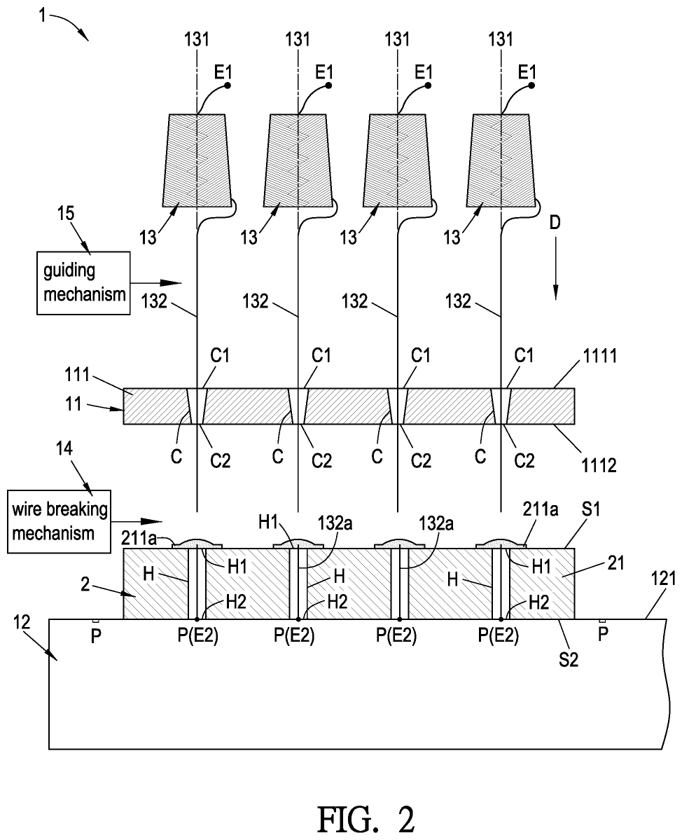

Referring to FIGS. 1 and 2, the manufacturing system 1 of this embodiment is used to manufacture an electronic device 2. The manufacturing system 1 includes a fixture 11, a target platform 12, a plurality of wire mechanisms 13, and a wire breaking mechanism 14. In addition, the manufacturing system 1 may further include a guiding mechanism 15.

The fixture 11 has a substrate 111, and the substrate 111 defines a plurality of channels C arranged separately. The channels C can be separately arranged at equal or irregular intervals on the substrate 111, and each channel C penetrates the upper surface 1111 of the substrate 111 and the lower surface 1112 of the substrate 111. In this embodiment, each channel C can be defined with a hole diameter not less than 25 μm. In this embodiment, the hole diameter of the channel C may be between 25 μm and 70 μm (25 μm≤hole diameter≤70 μm). In addition, two ends of each channel C of the fixture 11 define a channel opening C1 and a channel opening C2, respectively. In this embodiment, the target platform 12 is located at the lower side of the fixture 11. In each channel C, the channel opening C1 far away from the target platform 12 is located on the upper surface 1111 of the fixture 11, and the channel opening C2 close to the target platform 12 is located on the lower surface 1112 of the fixture 11. The channel opening C2 of each channel C close to the target platform 12 is not greater than the channel opening C1 of the same channel C far away from the target platform 12. That is, the channel opening C1 is larger than or equal to the channel opening C2. In this embodiment, the channel opening C1 is larger than the channel opening C2 for example. This design makes it easier for the wires to pass through the corresponding channels C. In some embodiments, the channel opening C2 may be not greater than 70 μm and not less than 15 μm, such as, for example, 70 μm, 60 μm or 50 μm. In addition, the substrate 111 of this embodiment further defines a wire-forward direction D. The wire-forward direction D is the direction from the upper surface 1111 of the substrate 111 to the lower surface 1112 of the substrate 111, and the wire-forward direction D is perpendicular to the upper surface 1111 or/and the lower surface 1112.

The target platform 12 defines a plane 121 and a plurality of target positions P arranged separately on the plane 121. In this embodiment, the target positions P may be the positions with specific marks or be virtually defined positions. In this case, the plane 121 is the upper surface of the target platform 12, and the target positions P can be separately arranged at equal or irregular intervals on the plane 121. In addition, the channels C of the fixture 11 correspond to at least part of the target positions P of the target platform 12. In this embodiment, the number of target positions P is greater than the number of the channels C, and one of the channels C corresponds to one target position P in the wire-forward direction D.

Each of the wire mechanisms 13 has a shaft 131 and a wire 132 wrapped around the shaft 131. In this embodiment, the wire 132 can be wrapped regularly or irregularly along the shaft 131 to form a wire reel or a wire ball, and each wire mechanism 13 can correspond to one of the channels C (i.e., the wire mechanisms 13 are arranged corresponding to the channel C in the one-to-one manner). Each wire 132 can define a fixed end E1 wrapping on the shaft 131 and a free end E2 opposite to the fixed end E1. The wire 132 of each wire mechanism 13 can pass through the corresponding channel C of the fixture 11, and the free end E2 of each wire 132 corresponds to one of the channels C and corresponds to one of the target positions P corresponding to the corresponding channel C. That is, one wire 132 corresponds to one channel C and one target position P corresponding to the corresponding channel C. As shown in FIG. 1, the fixed end E1 of each wire 132 is located at the upper side of the fixture 11 away from the target platform 12, and the free end E2 thereof is located at the lower side of the fixture 11. Herein, the free end E2 is located on the target platform 12 and corresponds to one of the target positions P.

In some embodiments, the material of each wire 132 can be a metal wire, such as gold, copper, or aluminum, or any combination thereof, or any alloy thereof. Each wire 132 is defined with a wire diameter, and the wire diameter is not less than 15 μm. In some embodiments, the wire diameter of each wire 132 can be greater than or equal to 15 μm and less than or equal to 55 μm (15 μm≤wire diameter≤55 μm). Herein, the wire diameter is the largest diameter of the wire 132, such as 25.4 μm (copper wire) or 50.8 μm (gold wire). It can be understood that the hole diameter of the channels C must be larger than the wire diameter of the wires 132, so that the wires 132 can pass through the corresponding channels C.

The guiding mechanism 15 is arranged at the upper side of the fixture 11 and is configured to guide the wires 132 toward the channels C of the fixture 11 correspondingly. In this embodiment, the guiding mechanism 15 can guide the wire 132 of each wire mechanism 13 to move in the wire-forward direction D, so that each wire 132 can pass through the corresponding channel C of the fixture 11 so as to correspond to one of the target positions P.

In this embodiment, the electronic device 2 is accommodated on the plane 121 of the target platform 12 and can include a substrate 21, a plurality of through holes H and at least one circuit layer. The substrate 21 has a first surface S1 (upper surface) and a second surface S2 (lower surface) opposite to each other. The substrate 21 can be a rigid substrate, a resilient substrate, or a composite substrate containing a rigid substrate and a resilient substrate. For example, the substrate 21 can be a glass substrate, a metal substrate, a ceramic substrate, a polyimide (PI) substrate, a common substrate for printed circuit board (e.g. FR4), or a composite substrate including at least one of the foregoing materials. This disclosure is not limited thereto.

The through holes H penetrate the substrate 21 and each connect the first surface S1 and the second surface S2 of the substrate 21. Each through hole H corresponds to one of the target positions P (i.e., one through hole H corresponds to one target position P). Each of the through holes H defines a hole opening H1 and a hole opening H2 opposite to each other. In this embodiment, the hole opening H1 is located on the first surface S1 of the substrate 21, and the hole opening H2 is located on the second surface S2 of the substrate 21. In some embodiments, the sizes of the hole openings H1 and H2 can be the same or different. In some embodiments, each through hole H can define a hole diameter, which can be the minimum hole diameter of the entire through hole H. The hole diameter of the through hole H can be greater than or equal to 15 μm, such as 15 μm, 20 μm, 30 μm, 50 μm, 100 μm, or etc. In this embodiment, the hole diameter of the through hole H can be a uniform value (i.e., the hole diameter is a constant value). In another embodiment, the hole diameter of the through hole H can be a non-uniform value. For example, the through hole H can be a tapered hole with a narrower middle part and wider top and bottom parts, or a tapered hole with a wider top part and a narrower bottom part, or a tapered hole with a narrower top part and a wider bottom part. This disclosure is not limited thereto.

The circuit layer can be arranged on the first surface S1 or the second surface S2, or on both of the first surface S1 and the second surface S2. In this embodiment, the circuit layer (the circuit layer 211a) is arranged on the first surface S1 as an example. In some embodiments, the circuit layer 211a can include a plurality of signal lines arranged perpendicular to and intersected to one another. In some embodiments, the signal lines can be conductive lines that can transmit electrical signals, such as scanning lines and/or data lines, depending on the functions and usages of the electronic device. In some embodiments, the material of the circuit layer 211a can include, for example, metals such as gold, copper, or aluminum, or any combination thereof, or an alloy of any combination thereof, or any of other conductive materials.

Therefore, in this embodiment, the free end E2 of the wire 132 of the wire mechanism 13 can pass through the corresponding channel C and the corresponding through hole H in sequence, and is located at one side of the electronic device 2 away from the fixture 11. That is, the free end E2 is located at the lower side of the substrate 21 and corresponds to the corresponding hole opening H2 and the corresponding target position P. In some embodiments, each wire 132 may or may not contact the hole wall of the corresponding through hole H.

The wire breaking mechanism 14 is located between the fixture 11 and the target platform 12. In this embodiment, the wire breaking mechanism 14 is located between the fixture 11 and the electronic device 2, and the wire breaking mechanism 14 is used to cut the wires 132 to form a plurality of wire segments 132a remained in the through holes H. In some embodiments, the wire breaking mechanism 14 includes, for example, a device for emitting a laser beam, a metal cutter with sharp cutting blade, or a cutting mechanism similar to the wire of grass cutter. To be noted, the laser beam can further provide the function of thermal welding.

In this embodiment, the wire breaking mechanism 14 cuts and welds one end of each wire segment 132a to the upper side of the electronic device. Specifically, in this embodiment, the manufacturing system 1 uses a wire breaking mechanism 14 (e.g. a laser device) that can emit laser beam to cut the wires 132, and while cutting each wire 132, it also welds one end of each wire segment 132a to the circuit layer 211a located on the first surface S1 of the substrate 21, so that the circuit layer 211a of the electronic device 2 can be electrically connected to each wire segment 132a. To be noted, this disclosure is not limited thereto. In another embodiment, a welding mechanism (not shown) can be provided to weld one end of each wire segment 132a to the circuit layer 211a of the electronic device 2 located on the first surface S1 or/and to weld the other end of each wire segment 132a to the circuit layer of the electronic device 2 located on the second surface S2 while or after the wire breaking mechanism 14 cuts the wires 132.

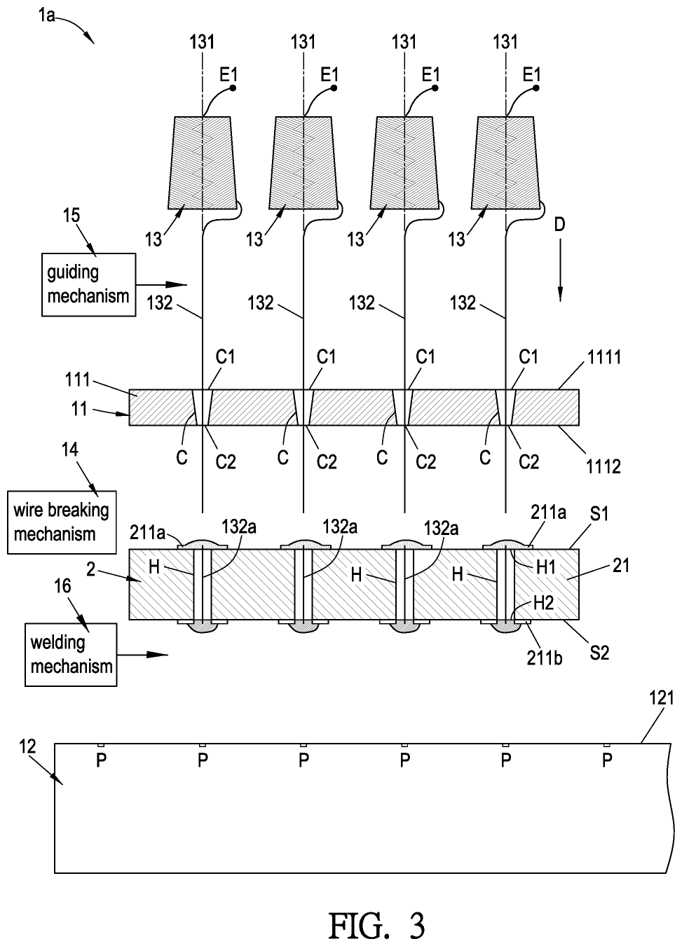

In addition, in another embodiment as shown in FIG. 3, a manufacturing system 1a, which is different from the manufacturing system 1, further includes a welding mechanism 16. The welding mechanism 16 is located at the lower side of the electronic device 2 away from the fixture 11. In this embodiment, a circuit layer 211a is arranged on the first surface S1 of the substrate 21, and another circuit layer 211b is arranged on the second surface S2 of the substrate 21. The welding mechanism 16 can be used to weld the free ends E2 of the wire segments 132a to the circuit layer 211b of the electronic device 2. In this case, the welding mechanism 16 can use, for example, hot air solder leveling to electrically connect the other end of each wire segment 132a to the circuit layer 211b located on the second surface S2 of the substrate 21, so that the circuit layer 211a on the upper surface of the electronic device 2 can be electrically connected to the circuit layer 211b on the lower surface of the electronic device 2 via the wire segments 132a. In this configuration, the electrical signals can be transmitted from the first surface S1 of the substrate 21 to the second surface S2 of the substrate 21, or from the second surface S2 of the substrate 21 to the first surface S1 of the substrate 21.

To be understood, as mentioned above, any ends of the wire segments 132a can be welded to the circuit layer of the electronic device by the wire breaking mechanism 14 (laser device) or the welding mechanism 16, and this disclosure is not limited thereto.

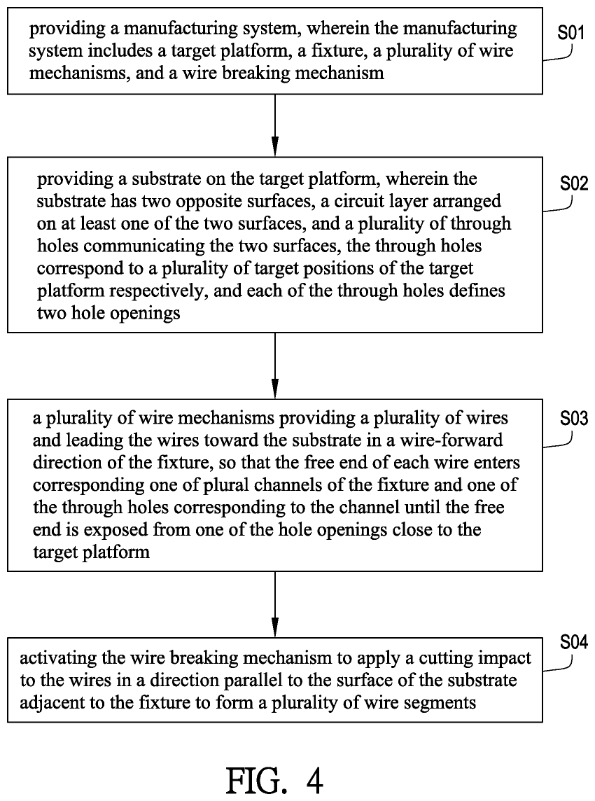

The manufacturing method of an electronic device of this disclosure will be described hereinafter with reference to FIG. 4 in view of the FIGS. 1 to 3. Herein, FIG. 4 is a flow chart of a manufacturing method of an electronic device according to an embodiment of this disclosure.

As shown in FIGS. 1 to 4, the manufacturing method of an electronic device of this disclosure includes the following steps S01 to S04. The step S01 is to provide a manufacturing system 1, wherein the manufacturing system 1 includes a target platform 12, a fixture 11, a plurality of wire mechanisms 13, and a wire breaking mechanism 14. The step S02 is to provide a substrate 21 on the target platform 12, wherein the substrate 21 has two opposite surfaces (i.e., the first surface S1 and the second surface S2), a circuit layer arranged on at least one of the two surfaces, and a plurality of through holes H communicating the two surfaces, the through holes H correspond to a plurality of target positions P of the target platform 12 respectively, and each of the through holes H defines two hole openings H1 and H2. In the step S03, a plurality of wire mechanisms 13 provide a plurality of wires 132 and lead the wires 132 toward the substrate 21 in a wire-forward direction D of the fixture 11, so that the free end E2 of each wire 132 enters corresponding one of plural channels C of the fixture 11 and one of the through holes H corresponding to the channel C until the free end E2 is exposed from one of the hole openings (the hole opening H2) close to the target platform 12. The step S04 is to activate the wire breaking mechanism 14 to apply a cutting impact to the wires 132 in a direction parallel to the surface (the first surface S1) of the substrate 21 adjacent to the fixture 11 to form a plurality of wire segments 132a.

In one embodiment, the cutting impact is a laser energy emitted from the wire breaking mechanism 14. In one embodiment, the manufacturing method can further include a step of: welding one end of each of the wire segments 132a (the top side of each wire segment 132a) to the circuit layer 211a of the electronic device 2. In one embodiment, the manufacturing method can further include a step of: welding one end of each of the wire segments 132a (the bottom side of each wire segment 132a) to the circuit layer 211b of the electronic device 2. In one embodiment, the manufacturing method can further include a step of: welding two end of each of the wire segments 132a to the circuit layers 211a and 211b of the electronic device 2 respectively. In one embodiment, this welding step is performed with a laser energy.

To be noted, the other technical descriptions of the manufacturing method of the electronic device can be referred to the embodiment of the above-mentioned manufacturing system 1 or 1a, so the detailed descriptions thereof will be omitted.

The manufacturing system and manufacturing method of the electronic device of this disclosure adapt the solution of implanting wires into through holes directly, and can be widely applied to the electronic devices with a large difference between the hole depth and the hole diameter (i.e., high depth-to-diameter ratio). This can reduce the risk of electrical connection failure in the case of utilizing chemical plating or electroplating to form connection in the through holes with small hole diameter. To be noted, the manufacturing system and manufacturing method of the present disclosure can further implement chemical plating or electroplating after the wires are implanted into the through holes. In addition, the electronic device used in the manufacturing system and manufacturing method of this disclosure can be formed with or without conductive circuits. For example, when the electronic device is formed with circuit layers, it can be manufactured as a final product. In addition, when the electronic device is not formed with the circuit layer, it should be transferred and electrically connected to another circuit board or terminal product. Accordingly, this disclosure can have a broader application range.

As mentioned above, compared with the conventional technology that uses chemical plating or electroplating process to form the conductive film to electrically connect the circuit layers on the upper and lower surfaces of the electronic device, the manufacturing system and manufacturing method of this disclosure can provide a manufacturing process with relatively simpler steps, lower cost, and more environmentally friendly. In addition, the manufactured products also have the advantages of reducing the failure rate of electrical connections and broader application range.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A manufacturing system of an electronic device, comprising:
a fixture having a substrate, wherein the substrate defines a plurality of channels;
a target platform located at one side of the fixture, wherein the target platform defines a plane and a plurality of target positions defined on the plane;
a plurality of wire mechanisms, wherein each of the wire mechanisms has a shaft and a wire wrapped around the shaft, each of the wires is defined with a fixed end wrapped around the shaft and a free end opposite to the fixed end, the channels of the fixture correspond to at least part of the target positions of the target platform, the wire mechanisms correspond to the channels, respectively, the free end of each of the wires corresponds to one of the channels, and corresponds to one of the target positions that corresponds to the corresponding channel, the wire of each of wire mechanisms passes through the corresponding channel of the fixture, the fixed end of the wire is located at the other side of the fixture away from the target platform, and the free end of the wire is located on the target platform and corresponds to one of the target positions; and
a wire breaking mechanism located between the fixture and the target platform, wherein the wire breaking mechanism is configured to cut the wires so as to form a plurality of wire segments.

2. The manufacturing system of claim 1, wherein each end of each of the channels defines a channel opening, and in each of the channels, the channel opening close to the target platform is not greater than the other channel opening away from the target platform.

3. The manufacturing system of claim 2, wherein the channel opening close to the target platform is not greater than 70 μm.

4. The manufacturing system of claim 1, wherein each of the channels is defined with a hole diameter not less than 25 μm.

5. The manufacturing system of claim 1, wherein each of the wires is defined with a wire diameter not less than 15 μm.

6. The manufacturing system of claim 1, wherein a hole diameter of the channels is greater than a wire diameter of the wires.

7. The manufacturing system of claim 1, wherein the substrate further defines a top surface and a wire-forward direction, each of the wires moves in the wire-forward direction, and the wire-forward direction is perpendicular to the top surface.

8. The manufacturing system of claim 1, further comprising:
a guiding mechanism configured to guide the wires toward the channels of the fixture correspondingly.

9. The manufacturing system of claim 1, wherein the electronic device is accommodated in the target platform, the electronic device defines a plurality of through holes, each of the through holes corresponds to one of the target positions, the free end of the wire of each of the wire mechanisms passes through corresponding one of the through holes and is located at one side of the electronic device away from the fixture, and the wire breaking mechanism cuts and welds one end of each of the wire segments to another side of the electronic device.

10. The manufacturing system of claim 1, further comprising:
a welding mechanism, wherein the electronic device is accommodated in the target platform, the electronic device defines a plurality of through holes, each of the through holes corresponds to one of the target positions, the welding mechanism is located at one side of the electronic device away from the fixture, and the welding mechanism welds the free end of each of the wires to the side of the electronic device.

11. A manufacturing method of an electronic device, comprising:
providing a manufacturing system, wherein the manufacturing system comprises a target platform, a fixture, a plurality of wire mechanisms and a wire breaking mechanism;
providing a substrate on the target platform, wherein the substrate has two opposite surfaces, a circuit layer arranged on at least one of the two surfaces, and a plurality of through holes communicating the two surfaces, the through holes correspond to a plurality of target positions of the target platform respectively, and each of the through holes defines two hole openings;
the plurality of wire mechanisms providing a plurality of wires and leading the wires toward the substrate in a wire-forward direction of the fixture, so that a free end of each of the wires enters corresponding one of a plurality of channels of the fixture and one of the through holes corresponding to the channel until the free end is exposed from one of the hole openings close to the target platform; and
activating the wire breaking mechanism to apply a cutting impact to the wires in a direction parallel to a surface of the substrate adjacent to the fixture to form a plurality of wire segments.

12. The manufacturing method of claim 11, wherein the cutting impact is a laser energy.

13. The manufacturing method of claim 11, further comprising:
welding one end of each of the wire segments to the circuit layer of the electronic device.

14. The manufacturing method of claim 13, wherein the step of welding is performed with a laser energy.
